(19) United States
(12) Patent Application Publication
(10) Pub. No.: US 2009/0092468 A1
(43) Pub. Date: Apr. 9, 2009

(54) Inlet port mechanism for introducing object and treatment system

(75) Inventors: Katsuhito Oyama, Oshu-shi (JP); Hiromi Nitadori, Oshu-shi (JP); Yasushi Takeuchi, Oshu-shi (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited

(21) Appl. No.: 12/285,321

(22) Filed: Oct. 1, 2008

(30) Foreign Application Priority Data
Oct. 3, 2007 (JP) 2007-259689

(51) Int. Cl. H01L 21/02; B65G 65/00

(52) U.S. Cl. 414/222.01; 414/271

(57) ABSTRACT

An inlet port mechanism for an object to be treated is provided to quickly and smoothly replace an atmosphere in a storage container body with an inert gas without shifting of the position of the object to be treated. The inlet port mechanism has a partition wall, a stage, an opening/closing door mechanism, a lid opening/closing mechanism, a gas injection unit, and an exhaust unit. The partition wall partitions a space into a container transfer area and an object transfer area and has an opening gate. The storage container body storing the object is placed on the stage. The opening/closing door mechanism has an opening/closing door that serves to open and close the opening gate. The lid opening/closing mechanism is provided with the opening gate and serves to open and close an opening/closing lid of the storage container body. The gas injection unit extends along an inner periphery of the opening gate to inject an inert gas into the storage container body and has a porous gas injection tube made of a porous material and having a cylindrical shape. The exhaust unit has an exhaust port for exhausting an atmosphere that is present in the storage container body and purged by the inert gas.

### CROSS-REFERENCE TO RELATED APPLICATION

The present application benefits from Japanese application JP2007-259689, filed on Oct. 3, 2007, the disclosure of which is hereby incorporated by reference in its entirety.

### BACKGROUND OF THE INVENTION

1. Field of the Invention

The present invention relates to an inlet port mechanism for introducing an object to be treated, such as a semiconductor wafer, from a storage container body for storing the object in an airtight manner into an object transfer area, and to a treatment system using the mechanism.

2. Background Art

In general, a film formation process, an oxidation treatment, a diffusion treatment, an etching treatment, and the like are repeatedly performed on a semiconductor wafer for manufacture of semiconductor integrated circuits such as an IC and LSI. In order to perform such a treatment, it is necessary that the semiconductor wafer be transferred from one apparatus to another apparatus.

In this case, in order to improve the yield, it is necessary to prevent a particle and a native oxide from being attached to and formed on the surface of the semiconductor wafer, as already known. In connection with the necessity, a storage container body capable of storing a plurality of wafers and having an airtight inner space is often used to carry the wafers in response to an increase in demand on high integration of semiconductor devices and miniaturization of the devices. As this type of storage container body, FOUP (registered trademark) is generally known (refer to, for example, JP-A-H08-279546, JP-A-H09-306975, and JP-A-H11-274267).

This type of storage container body is filled with highly cleaned air in order to prevent a particle and the like from being attached to the surfaces of the semiconductor wafers.

In general, a treatment system using the storage container body has a container transfer area and an object transfer area (refer to, for example, JP-A-2003-37148, JP-A-2004-22674 and JP-A-2005-79250). In the container transfer area, the storage container body is transferred by a transfer mechanism. In the object transfer area, after an opening/closing lid of the storage container body is removed, the semiconductor wafer is transferred from the inner space of the storage container body to a wafer boat or the like and subjected to a heat treatment. The two areas are partitioned by a partition wall having an opening gate that is openable and closable and used to transfer the semiconductor wafer. The object transfer area in which an object to be treated is transferred while the object is exposed to an atmosphere, the object transfer area is filled with an inert gas such as a nitrogen atmosphere in order to prevent a native oxide film or the like from being attached to the surface of the semiconductor wafer.

A storage container body capable of storing about 25 wafers each having a diameter of 300 mm (12 inches) has a capacity of about 40 to 45 liters depending on wafer size used in manufacture. When the storage container body is opened through the opening gate on the side of the object transfer area, cleaned air in the storage container body flows to the object transfer area that is filled with a nitrogen atmosphere. As a result, the nitrogen atmosphere is diluted by a large amount of the cleaned air. This reduces the advantage that the object transfer area is filled with the nitrogen atmosphere.

As disclosed in JP-A-H11-274267, JP-A-2004-22674, and IP-A-2005-79250, inert gas replacement means is provided, or a nitrogen gas nozzle is provided at an inlet port. In this configuration, a nitrogen gas is introduced into a storage container body and replaced with an atmosphere present in the storage container body before the storage container body is open on the side of the object transfer area.

### SUMMARY OF THE INVENTION

In a conventional structure as disclosed in JP-A-H11-274267 and JP-A-2005-79250, the introduced inert gas is injected from a gas injection hole or the like, and directly collides with a wafer. The momentum of the injected gas may cause the wafer to be blown or cause the position of the wafer to be shifted. In order to prevent this, it is necessary that the flow rate and the flow amount of the gas be suppressed. Due to the suppression, it takes much time to replace the inert gas with the atmosphere present in the storage container body. This results in a reduction in throughput. In addition, the introduced inert gas may leak to an area where an operator works. It is, therefore, requested to improve safety against the leak.

In a conventional structure as disclosed in JP-A-2004-22674, an N₂ gas is injected from a nozzle and collides with a member other than a wafer. Such a collision reduces the momentum of the N₂ gas. After that, the N₂ gas is introduced into an area in which a wafer is present, and replaced with an atmosphere present in the area. In this case, although the injected N₂ gas collides with the member to reduce the momentum of the N₂ gas, the N₂ gas is injected from a specified injection hole of the nozzle. Thus, the momentum of the N₂ gas prevails still, and the position of the wafer may be shifted due to undesirable motion of the wafer.

It is, therefore, an object of the present invention to provide an inlet port mechanism for introducing an object to be treated, and a treatment system using the inlet port mechanism. The inlet port mechanism is capable of quickly and smoothly replacing an atmosphere present in a storage container body with an inert gas to improve the throughput without shifting of the position of the object (to be treated) stored in the storage container body.

According to an aspect of the present invention, an inlet port mechanism for introducing an object to be treated, from a storage container body that has an opening/closing lid and is located in a container transfer area into an object transfer area filled with an inert gas atmosphere, the mechanism comprises: a partition wall that partitions a space into the container transfer area and the object transfer area and has an opening gate for passing the object to be treated under the condition that the storage container body is in contact with the partition wall; a stage that is provided at the container transfer area for placing the storage container body thereon; an opening/closing door mechanism having a opening/closing door that serves to open and close the opening gate on the side of the object transfer area, the opening gate being provided in the partition wall; a lid opening/closing mechanism that is provided at the opening/closing door and adapted to open and close the opening/closing lid of the storage container body; gas injection means that extends along an inner periphery of the opening gate to inject an inert gas into the storage container body and has a porous gas injection tube made of a porous material and having a cylindrical shape; and exhaust means that extends along another inner periphery of the opening gate and has an exhaust port for exhausting an atmosphere that is present in the storage container body and purged by the inert gas injected from the porous gas injection tube.

According to another aspect of the present invention, the porous gas injection tube includes a filter function having a filtration property to remove a particle having a diameter of more than a certain value in a range of several nanometers to several hundred nanometers. In addition, an edge portion of the opening/closing door is bent toward the opening gate. The opening/closing door has a turned square U-shaped vertical cross section and a turned square U-shaped horizontal cross section.

According to still another aspect of the present invention, the opening gate is formed into a quadrangular shape. The porous gas injection tube extends along at most three sides of the opening gate. The porous gas injection tube is made of one or more selected from the group consisting of a porous metal material, a porous ceramic material and a porous resin material.

According to still another aspect of the present invention, a treatment system for introducing an object to be treated, from a storage container body that has an opening/closing lid and is located in a container transfer area into an object transfer area filled with an inert gas atmosphere, and subjecting the object to a heat treatment, the treatment system comprises: an inlet port mechanism for introducing the object from the container transfer area to the object transfer area; a treatment chamber that is provided in the object transfer area and in which the heat treatment is performed on the object; an object boat that is provided in the object transfer area and capable of mounting a plurality of objects at a plurality of stages; a port elevating mechanism that is provided in the object transfer area and lifts and lowers the object boat to insert and extract the object boat into and out of the treatment chamber; and an object transfer mechanism that is provided in the object transfer area and transfers the object between the object boat and the storage container body under the condition that the opening/closing lid of the storage container body is in an open state, wherein the inlet port mechanism has: a partition wall that partitions a space into the container transfer area and the object transfer area and has an opening gate for passing the object to be treated under the condition that the storage container body is in contact with the partition wall; a stage that is provided at the container transfer area for placing the storage container body thereon; an opening/closing door mechanism having a opening/closing door that serves to open and close the opening gate on the side of the object transfer area, the opening gate being provided in the partition wall; a lid opening/closing mechanism that is provided at the opening/closing door and adapted to open and close the opening/closing lid of the storage container body; gas injection means that extends along an inner periphery of the opening gate to inject an inert gas into the storage container body and has a porous gas injection tube made of a porous material and having a cylindrical shape; and exhaust means that extends along another inner periphery of the opening gate and has an exhaust port for exhausting an atmosphere that is present in the storage container body and purged by the inert gas injected from the porous gas injection tube.

The inlet port mechanism and the treatment system according to the present invention provide the following excellent effects. That is, the inert gas is injected from the gas injection means having the cylindrical porous gas injection tube that extends along the inner periphery of the opening gate and is made of the porous material. In this configuration, the inert gas is injected from the entire surface of the porous gas injection tube. Therefore, the momentum or the flow rate of the injected inert gas can be sufficiently reduced. The replacement of the atmosphere present in the storage container body with the inert gas can be quickly and smoothly performed to improve the throughput without shifting of the position of the object.

### BRIEF DESCRIPTION OF THE DRAWINGS

FIGS. 1A and 1B are perspective views of a general storage container body for storing an object to be treated.

FIG. 2 is a diagram showing a treatment system having an inlet port mechanism for introducing an object to be treated, according to the present invention.

FIG. 3 is a plan view of an opening/closing door covering an opening gate when the opening/closing door is viewed from the side of an object transfer area.

FIG. 4 is a plan view of a stage of the inlet port mechanism.

FIGS. 5A and 5B are cross sectional views of a storage container body placed on the inlet port mechanism.

FIGS. 6A and 6B are diagrams each showing a porous gas injection tube of a gas injection unit.

FIG. 7 is a diagram showing an operation to be performed when an opening/closing lid of the storage container body placed on the stage is removed.

FIG. 8 is a diagram showing an operation to be performed when the opening/closing lid of the storage container body placed on the stage is removed.

FIG. 9 is a diagram showing an operation to be performed when the opening/closing lid of the storage container body placed on the stage is removed.

### DESCRIPTION OF THE PREFERRED EMBODIMENTS

A description will be made of an inlet port mechanism for introducing an object to be treated, and a treatment system using the inlet port mechanism, according to an embodiment of the present invention, with reference to the accompanying drawings.

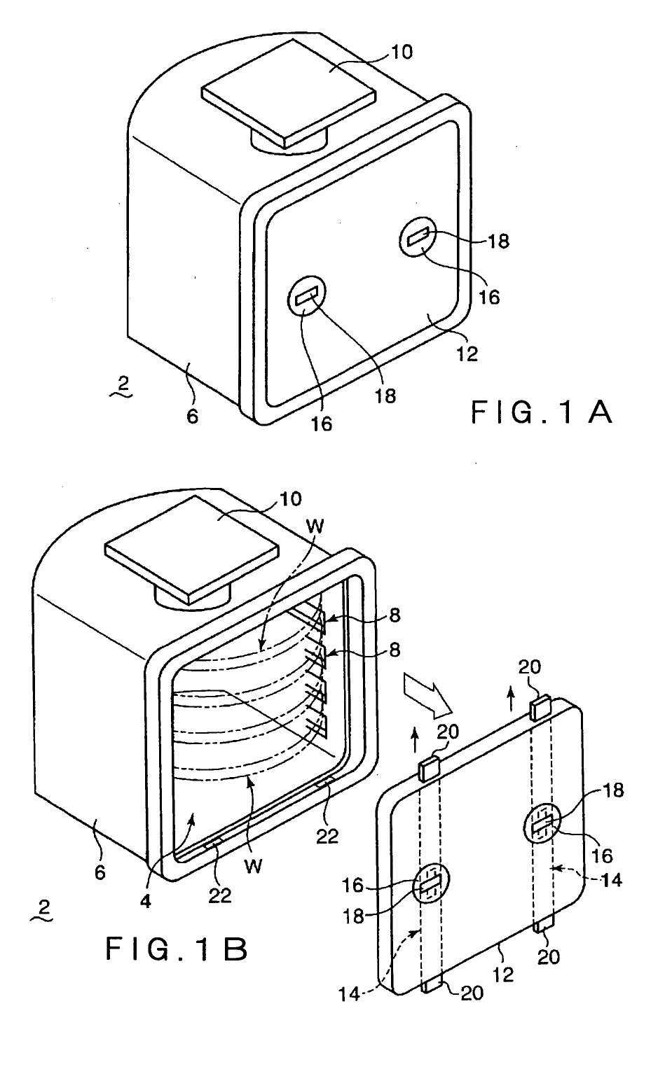

First, a storage container body 2 will be described with reference to FIGS. 1A and 1B. FIG. 1A is a perspective view of the storage container body 2 that is in the state before an opening/closing lid 12 is removed. FIG. 1B is a perspective view of the storage container body 2 that is in the state after the opening/closing lid 12 is removed.

As shown in FIGS. 1A and 1B, the storage container body 2 has an opening section 4 on one side thereof and a semi-elliptical box container 6 on another side thereof. Support members 8 each having a shelf shape or a groove shape are provided on an inner wall of the box container 6 and arranged at a plurality of stages. Each of the support members 8 holds an edge portion of a semiconductor wafer W (used as an object to be treated) having a diameter of, for example, 300 mm. The support members 8 are arranged to ensure that the semiconductor wafers W are stored in the box container 6 at the plurality of stages and at substantially equal intervals. A grip 10 to hold the entire box container 6 is provided on a ceiling portion of the box container 6. Typically, about 13 or 25 semiconductor wafers W can be stored in the single box container 6.

A quadrangular plate-shaped opening/closing lid 12 is detachably attached to the opening section 4 of the storage container body 2 to hermetically seal the box container 6. An inner space of the box container 6 is filled with cleaned air.

Two lock mechanisms 14 are provided for the opening/closing lid 12. The lock mechanisms 14 are unlocked to allow the opening/closing lid 12 to be removed from the opening section 4. Each of the lock mechanisms 14 has a disk-like lock plate 16 rotatably attached thereto. The lock plates 16 are located at substantially central portions of the lock mechanisms 14 in longitudinal directions of the lock mechanisms 14, respectively. Each of the lock plates 16 has an elongated, concave key groove 18. Each of the lock plates 16 is connected with a pair of protruding pins 20 via a crank mechanism (not shown) for converting an arc motion into a linear motion. The protruding pins 20 are located at upper and lower end portions of each of the lock plates 16. Each of the lock plates 16 forwardly or reversely rotates by 90 degrees to cause the protruding pins 20 to protrude from the opening/closing lid 12 in the longitudinal direction of the lock mechanism 14.

When the lock mechanism 14 is locked, edge portions of each of the extractable pins 20 are respectively inserted in and engaged with pin holes 22 located at upper and lower portions of the opening section 4. This prevents the opening/closing lid 12 from being removed from the opening section 4. It should be noted that only the pin holes 22 located at the lower portion of the opening section 4 are shown in FIG. 1B.

In addition, a plurality of positioning recessed portions (not shown) are provided on a lower surface of a bottom portion of the box container 6 (storage container body 2). The positioning recessed portions are used to position the storage container body 2 and to thereby place the storage container body 2 on a stage or the like (described later). Furthermore, a lock piece (not shown) serving as a box fixing section is provided on the lower surface of the bottom portion of the box container 6. When the lock piece is coupled with a rotation hook (described later), the lock piece locks the storage container body 2 to ensure that the storage container body 2 does not move on the stage.

As the box fixing section, a pressing section may be provided to press the storage container body 2 placed on the stage from the upper side of the storage container body 2 in order to fix the storage container body 2, in place of the lock piece and the rotation hook.

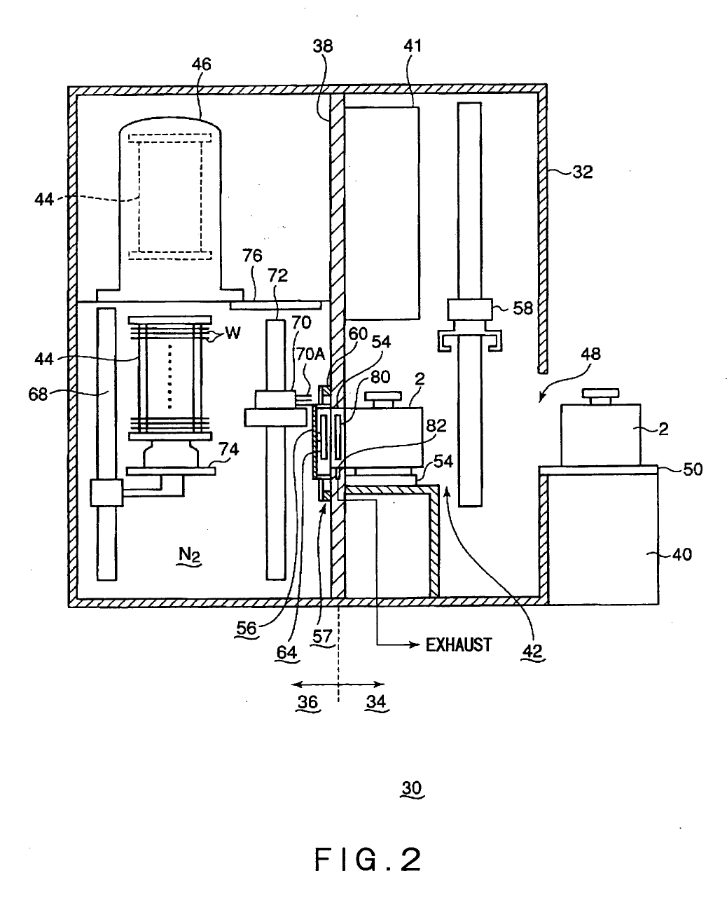

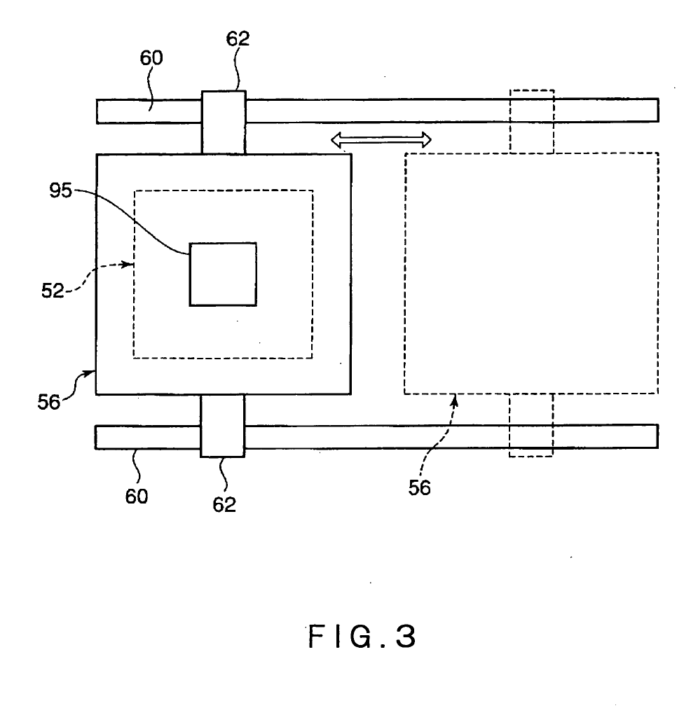

Next, a description will be made of the treatment system having the inlet port mechanism for introducing an object to be treated, according to the present invention, with reference to FIGS. 2 and 3.

As shown in FIG. 2, a treatment system 30 for an object to be treated is surrounded by a case 32 that is entirely made of stainless or the like. An inner space of the case 32 is divided into a container transfer area 34 and a wafer transfer area 36 by means of a partition wall 38. The container transfer area 34 is used to transfer the storage container body 2. The wafer transfer area 36 is provided as an object transfer area. The wafer transfer area 36 is used to transfer a semiconductor wafer W (that is an object to be treated) while the semiconductor wafer W is exposed to an atmosphere present in the wafer transfer area 36.

Cleaned air flows downward in the container transfer area 34. The wafer transfer area 36 is sealed. An N₂ gas or a rare gas such as an Ar gas is supplied into the wafer transfer area 36. The wafer transfer area 36 is filled with an inert gas atmosphere. In the embodiment, the wafer transfer area 36 is filled with an N₂ gas atmosphere.

The treatment system 30 includes a load port 40, a stocker 41, an inlet port mechanism 42 and a treatment chamber 46. The load port 40 is adapted to carry the storage container body 2 into and out of the treatment system 30. The stocker 41 is adapted to temporarily store the storage container body 2. The inlet port mechanism 42 introduces the wafer W from the storage container body 2 into the wafer transfer area 36, and then transfers the wafer W to an object boat 44. The wafer W is then held by the object boat 44. The treatment chamber 46 is adapted to subject the wafer W held by the object boat 44 to a predetermined heat treatment.

A box inlet/outlet port 48 is provided at one surface of the case 32 to pass the storage container body 2 placed on an outside stage 50 (that is provided on the load port 40). The box inlet/outlet port 48 is constantly open. The outside stage 50 is provided on the outside of the inlet/outlet port 48 and mounts thereon the storage container body 2 transferred from an external area. The outside stage 50 is horizontally movable toward the inside of the case 32.

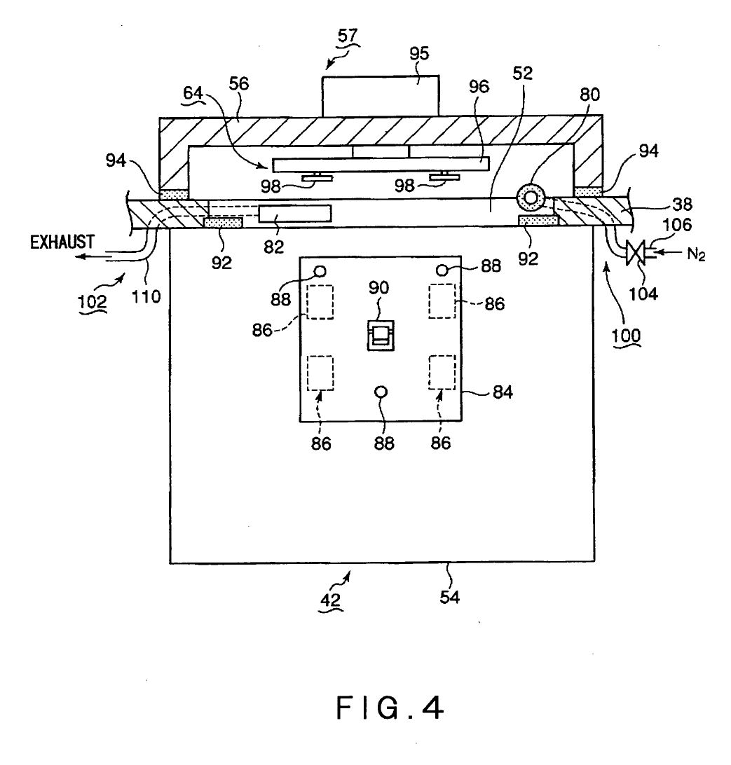

The stocker 41 has therein shelves or the like for temporarily holding and storing the storage container bodies 2 in two rows at two stages, for example. In addition, an opening gate 52 (shown in FIG. 4) is provided at a location at which the inlet port mechanism 42 is present. It should be noted that a plurality of the opening gates 52 may be provided. The opening gate 52 is provided in the partition wall 38 for partitioning the inner space of the case 32 into the areas 34 and 36. The opening gate 52 has an opening of which the size is substantially the same as that of the opening section 4 of the storage container body 2.

A single horizontally oriented stage 54 is provided on the side of the container transfer area 34 with respect to the opening gate 52. The storage container body 2 can be placed on the stage 54. A container transfer mechanism 58 having an elevating function is provided between the stage 54 and the load port 40. The container transfer mechanism 58 is capable of transferring the storage container body 2 between the load port 40 and the stocker 41, between the stocker 41 and the stage 54, and between the load port 40 and the stage 54.

A door mechanism 57 is provided on the side of the wafer transfer area 36 with respect to the opening gate 52. The door mechanism 57 has an opening/closing door 56 for opening and closing the opening gate 52. The configuration of the door mechanism 57 will be described later.

Guide rails 60 are provided above and under the opening/closing door 56 as shown in FIG. 3. The opening/closing door 56 is held by a pair of arms 62. The arms 62 moves along the guide rails 60, respectively. After the opening/closing door 56 is slightly separated from the opening gate 52, the opening/closing door 56 slides along the guide rails 60 in a horizontal direction to open and close the opening gate 52.

The opening/closing door 56 is provided with a lid opening/closing mechanism 64 adapted to open and close the opening/closing lid 12 of the storage container body 2. As described above, lid opening/closing mechanisms disclosed in JP-A-H08-279546, JP-A-H11-274267, and JP-A-2005-79250 and the like may be used as the lid opening/closing mechanism 64.

A boat elevating mechanism 68 is provided in the wafer transfer area 36. The boat elevating mechanism 68 is adapted to lift and lower the object boat 44 (which is a wafer boat or the like). An object transfer mechanism 70 is provided between the boat elevating mechanism 68 and the inlet port mechanism 42. The object transfer mechanism 70 is capable of turning and is extendable. The object transfer mechanism 70 is movable upward and downward by means of an elevator 72 and has an arm 70A. The arm 70A of the object transfer mechanism 70 is driven to be extendable, turn and move upward and downward to allow the wafers W to be transferred between the object boat 44 and the storage container body 2 placed on the stage 54. In this case, a plurality of the arms 70A is provided. When the number of the arms 70A is five, wafers up to five wafers can be transferred at one time.

The object boat 44 is made of quartz or the like. The object boat 44 is capable of holding about 25 to 150 wafers at multiple stages at a predetermined pitch. The treatment chamber 46 is made of quartz and has a cylindrical shape. The treatment chamber 46 is located on the upper side of the object transfer area 36. A heater (not shown) is provided around the treatment chamber 46 to ensure that a large number of wafers W are subjected to a predetermined heat treatment such as a film formation process, an oxidation treatment and a diffusion treatment at one time.

A cap 74 is provided under the treatment chamber 46. The cap 74 is movable upward and downward by means of the boat elevating mechanism 68. The object boat 44 can be loaded into the treatment chamber 46 from a lower opening section of the treatment chamber 46 by lifting the object boat 44 under the condition that the object boat 44 is placed on the cap 74. In this case, the cap 74 closes the lower opening section of the treatment chamber 46 in an airtight manner.

A shutter 76 is provided at the lower opening section of the treatment chamber 46. The shutter 76 can slide to close the lower opening section of the treatment chamber 46. A porous gas injection tube 80 extends along an inner periphery of the opening gate 52 of the inlet port mechanism 42. An exhaust port 82 extends along another inner periphery of the opening gate 52 of the inlet port mechanism 42. The porous gas injection tube 80 and the exhaust port 82 are features of the present invention.

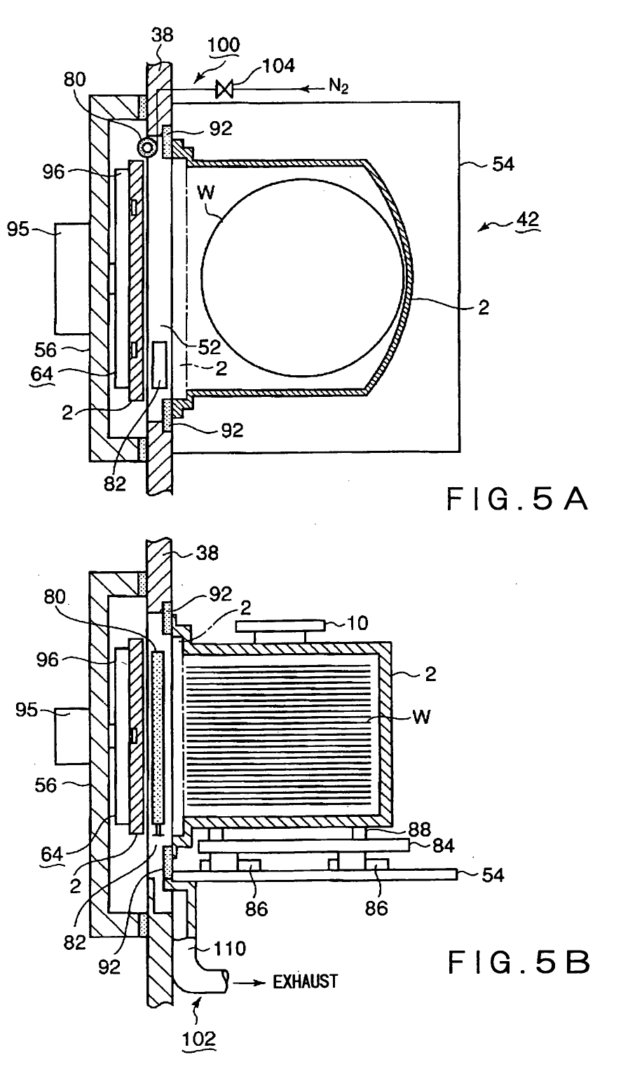

The inlet port mechanism 42, and the structures of the porous gas injection tube 80 and the exhaust port 82, will be described in detail with reference to FIGS. 4, 5A and 5B.

FIG. 5A is a transverse cross sectional view of the storage container body 2 placed on the inlet port mechanism 42. FIG. 5B is a vertical cross sectional view of the storage container body 2 placed on the inlet port mechanism 42.

As shown in FIGS. 4, 5A and 5B, the stage 54 has a slide base 84 on the upper side thereof. The slide base 84 is located above two pairs of guide rails 86. The slide base 84 is capable of sliding toward the opening gate 52. A plurality of positioning protrusions 88 are provided on an upper surface of the slide base 84. In an example shown in FIGS. 4, 5A and 5B, the number of the positioning protrusions 88 is three. The positioning protrusions 88 are engaged with the positioning recessed portions (not shown) provided on the lower surface of the bottom portion of the storage container body 2 to position the storage container body 2. The storage container body 2 is placed directly on the slide base 84.

In addition, a rotation hook 90 (shown in FIG. 4) is provided at a central portion of the slide base 84. The rotation hook 90 is rotatable. The rotation hook 90 is hooked to the lock piece (not shown) provided on the lower surface of the bottom portion of the storage container body 2 to allow the storage container body 2 to be fixed to the slide base 84. The slide base 84 slides to the opening gate 52 under the condition that the storage container body 2 is fixed to the slide base 84 to ensure that a front edge portion of the storage container body 2 comes in contact with an edge portion of the opening gate 52.

The opening gate 52 is formed into a quadrangular shape (shown in FIG. 3). A seal member 92 made of fluorine rubber or the like is provided around the opening gate 52 on the side of the container transfer area 34. As described above, the front edge portion of the storage container body 2 comes in contact with the seal member 92 and is pressed against the seal member 92. Therefore, the sealing performance of the storage container body 2 and the opening gate 52 is ensured.

As described above, the opening/closing door 56 serves to open and close the opening gate 52 on the side of the wafer transfer area 36 with respect to the opening gate 52. An edge portion of the opening/closing door 56 is bent toward the opening gate 52. The opening/closing door 56 has a turned square U-shaped vertical cross section and a turned square U-shaped horizontal cross section. That is, the opening/closing door 56 is formed like a box that is open on one side thereof. An opening of the opening/closing door 56 is designed to be slightly larger than an opening of the opening gate 52.

A seal member 94 made of fluorine rubber or the like is provided on a tip portion of the opening/closing door 56 as shown in FIG. 4. The seal member 94 comes in contact with another edge portion of the opening gate 52 to improve sealing performance between the opening gate 52 and the opening/closing door 56. After the opening/closing door 56 moves to slightly separate from the partition wall 38, the opening/closing door 56 can move by a predetermined distance along the guide rails 60 (shown in FIG. 3) in the horizontal direction.

The opening/closing door 56 is provided with the lid opening/closing mechanism 64 in an integrated manner. The lid opening/closing mechanism 64 is driven by an actuator 95 to open and close the opening/closing lid 12 of the storage container body 2 (refer to FIGS. 5A and 5B). Specifically, the lid opening/closing mechanism 64 has a base 96 capable of independently moving forward and backward. A pair of keys 98 is provided on the base 96. The keys 98 are rotatable and arranged side by side in the horizontal direction (refer to FIG. 4). The keys 98 are engaged with the key grooves 18 (shown in FIGS. 1A and 1B) of the opening/closing lid 12 and clockwise or counterclockwise rotated to lock and unlock the lock mechanism 14.

A gas injection unit 100 and an exhaust unit 102, which are features of the present invention, are provided at a periphery of the opening gate 52. The gas injection unit 100 injects an inert gas. The exhaust unit 102 exhausts an atmosphere that is present in the storage container body 2 and purged by the injection of the inert gas. Specifically, the gas injection unit 100 extends along the inner periphery of the opening gate 52 and has the porous gas injection tube 80. The porous gas injection tube 80 is made of a porous material and formed into a cylindrical shape.

The porous gas injection tube 80 extends along one side (extending in a vertical direction) of the quadrangular opening gate 52 or along the edge portion of the opening gate 52. The porous gas injection tube 80 is located to ensure that the porous gas injection tube 80 does not interfere with the opening/closing lid 12 that is capable of being removed from and attached to the storage container body 2.

A metal mesh porous material made of, for example, stainless steel may be used as the porous material. A lower edge portion of the porous gas injection tube 80 is connected with a gas inlet tube 106 having an opening/closing valve 104 provided in the middle of the gas inlet tube 106. The gas inlet tube 106 is adapted to supply to the porous gas injection tube 80 an N₂ gas as an inert gas if necessary, for example.

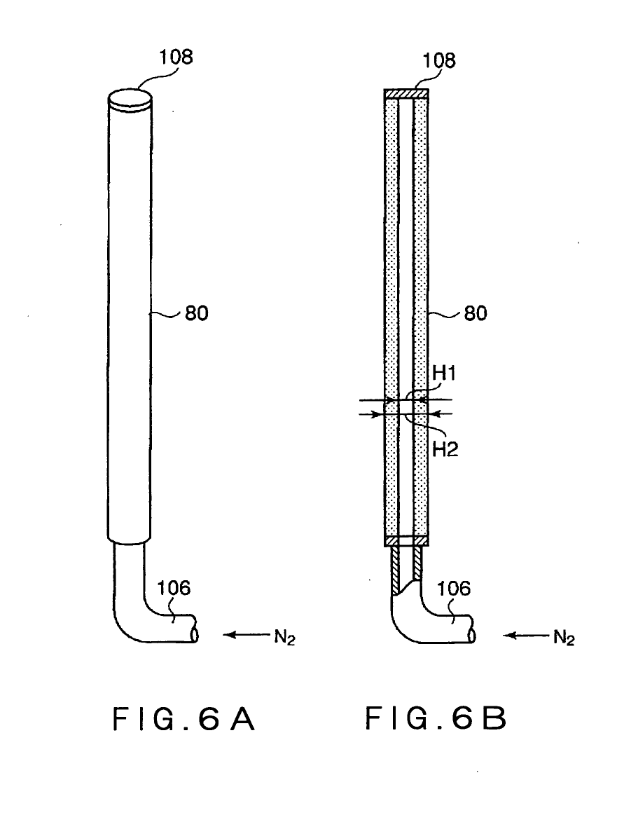

FIG. 6A is a perspective view of the porous gas injection tube 80. FIG. 6B is a side cross sectional view of the porous gas injection tube 80.

As shown in FIGS. 6A and 6B, the porous gas injection tube 80 is made of the porous material having air permeability and is formed into the cylindrical shape. The porous gas injection tube 80 is hollow. An upper edge portion of the porous gas injection tube 80 is sealed by a seal member 108. The N₂ gas is introduced in the porous gas injection tube 80 and ascends in the porous gas injection tube 80. While the flow rate of the N₂ gas is reduced, the N₂ gas is injected from the entire circumference of the porous gas injection tube 80. In this case, since the N₂ gas is injected from the entire surface of the porous gas injection tube 80 (i.e., the N₂ gas is injected from all areas (in the vertical direction) of the porous gas injection tube 80 and the entire circumference of the porous gas injection tube 80), a large amount of the N₂ gas can be injected under the condition that the flow rate of the N₂ gas is reduced.

The porous material has a filter function for removing a particle contained in the N₂ gas. A filtration property of the filter function of the porous material is set to remove a particle having a diameter of more than a certain value in a range of several nanometers to several hundred nanometers, for example, a diameter of more than 20 nanometers. In FIG. 6B, the inner diameter H1 of the porous gas injection tube 80 is approximately 4 mm to 10 mm, while the outer diameter H2 of the porous gas injection tube 80 is approximately 6 mm to 12 mm. The height (measured in the vertical direction) of the porous gas injection tube 80 is slightly smaller than the height (measured in the vertical direction) of the opening gate 52.

The material used as the porous material may be one or more selected from the group consisting of a porous metal material using aluminum or the like; a porous ceramic material using alumina or the like; and a porous resin material using Teflon (registered trademark), PEEK (registered trademark) or the like.

The exhaust unit 102 has the exhaust port 82 provided at the inner periphery of the opening gate 52. The position of this inner periphery of the opening gate 52 at which the exhaust port 82 is provided is different from that of the inner periphery of the opening gate 52 at which the porous gas injection tube 80 is provided. Specifically, the exhaust port 82 is located at a bottom portion of the opening gate 52 and on the side opposite to the porous gas injection tube 80. The exhaust port 82 is connected with an exhaust path 110. The exhaust path 110 is connected with a factory exhaust duct (not shown) or the like. The atmosphere that is present in the storage container body 2 and purged by the N₂ gas is efficiently sucked via the factory exhaust duct or the like in a constant manner and exhausted.

Next, operations of the treatment system having the configuration described above will be described.

The entire flow of transfer of the semiconductor wafer W will be described. As shown in FIG. 2, the storage container body 2 placed on the outer stage 50 (provided on the load port 40) from an external place is introduced into the container transfer area 34 (filled with cleaned air) by the container transfer mechanism 58. Then, the storage container body 2 is placed on the stage 54 of the inlet port mechanism 42 after the storage container body 2 is temporarily stored in the stocker 41. Alternatively, the storage container body 2 is directly placed on the stage 54 of the inlet port mechanism 42 without being stored in the stocker 41.

Subsequently, the opening/closing lid 12 of the storage container body 2 is opened by the lid opening/closing mechanism 64. After that, the cleaned air in the storage container body 2 is replaced with the nitrogen gas injected from the porous gas injection tube 80 of the gas injection unit 100. Then, the opening/closing door 56 slides in the horizontal direction to open the opening gate 52. These operations allow the storage container body 2 to be open on the side of the wafer transfer area 36.

The semiconductor wafers W placed in the storage container body 2 are transferred to the object boat 44 by the object transfer mechanism 70 (located in the wafer transfer area 36) in groups of multiple semiconductor wafers W. After the transfer of the wafers W is completed, the boat elevating mechanism 68 is driven to insert the wafers W into the treatment chamber 46 that is located above the object boat 44. Then, the wafers W is subjected to a predetermined heat treatment in the treatment chamber 46. The wafers W subjected to the heat treatment are carried out of the treatment system in a route opposite to the described route.

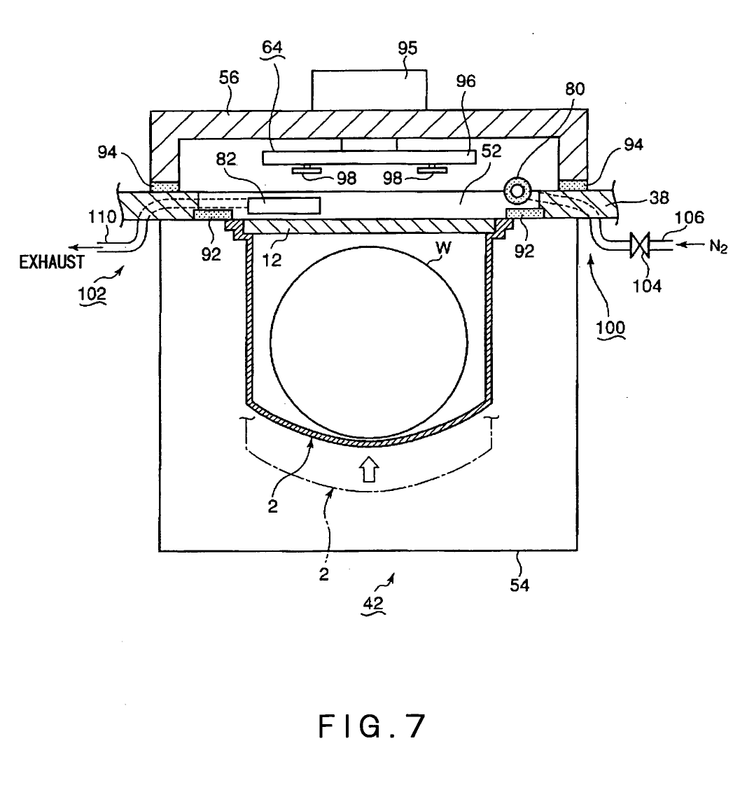

Next, operations of the inlet port mechanism 42 will be described with reference to FIGS. 7 to 9.

The storage container body 2 is directly placed on the slide base 84 (shown in FIG. 4) of the stage 54. In this case, the positioning recessed portions (not shown) provided on the lower surface of the bottom portion of the storage container body 2 are respectively engaged with the positioning protrusions 88 provided on the slide base 84 to position the storage container body 2 on the slide base 84 (or to fix the storage container body 2 to the slide base 84).

The rotation hook 90 rotates to be coupled with the lock piece (not shown) of the storage container body 2 and thereby be fixed to the lock piece. Then, the slide base 84 moves in the horizontal direction toward the opening gate 52 to ensure that the edge portion of the storage container body 2 comes in contact with the seal member 92 provided around the opening gate 52. This state is shown in FIG. 7. At this time point, the opening gate 52 is in a completely closed state by means of the opening/closing door 56.

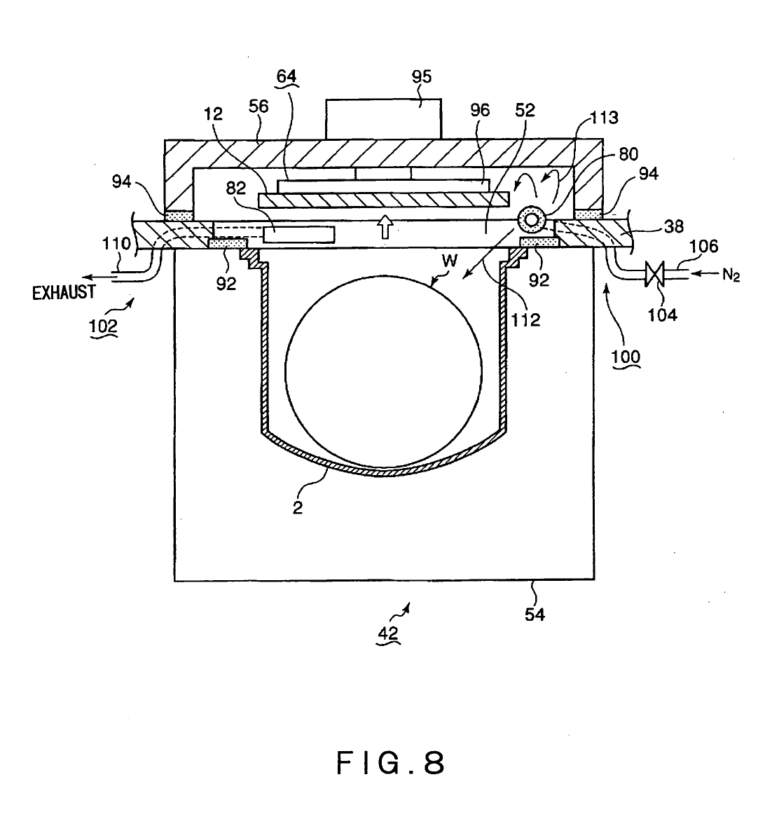

Next, the lid opening/closing mechanism 64 provided at the opening/closing door 56 is driven to insert the keys 98 in the key grooves 18 (shown in FIGS. 1A and 1B) of the opening/closing lid 12 and to rotate the keys 98 so that the lock mechanism 14 is unlocked. Performing this operation remove the opening/closing lid 12 to open the storage container body 2 filled with the cleaned air, as shown in FIG. 8. Next, in order to replace the cleaned air with an N₂ gas, a large amount of the nitrogen (N₂) gas is supplied into the porous gas injection tube 80 of the gas injection unit 100 as the inert gas.

The N₂ gas supplied into the porous gas injection tube 80 ascends in the porous gas injection tube 80, while being injected from the entire circumference of the porous gas injection tube 80 in a direction indicated by an arrow 112 (shown in FIG. 8). The N₂ gas injected from the porous gas injection tube 80 flows into the storage container body 2 that is in an open state and purges the cleaned air in the storage container body 2 to remove the cleaned air from the storage container body 2. The purged cleaned air in the storage container body 2 is sucked by the exhaust port 82 (located at the bottom portion of the opening gate 52 and on the side opposite to the porous gas injection tube 80 with respect to the opening gate 52) of the exhaust unit 102 and exhausted out of the system.

In order to supply a large amount of the N₂ gas from the gas injection unit 100, the rate of flow of the N₂ gas in the gas inlet tube 106 of the gas injection unit 100 is set to be significantly high. After the N₂ gas is introduced into the porous gas injection tube 80, the N₂ gas is injected from the entire surface of the porous gas injection tube 80 (i.e., the N₂ gas is injected from the all areas (in the vertical direction) of the porous gas injection tube 80 and the entire circumference of the porous gas injection tube 80). Therefore, a large amount of the N₂ gas can be injected from the porous gas injection tube 80 under the condition that the flow rate of the N₂ gas is remarkably reduced. In this case, the N₂ gas injected directly toward the wafers W flows into the storage container body 2.

The N₂ gas injected toward the side opposite to the wafers W collides with the opening/closing door 56 or the like and is returned and directed to the storage container body 2, as indicated by arrows 113 shown in FIG. 8. Then, the returned N₂ gas flows into the storage container body 2. In both cases, the flow rate of the N₂ gas is significantly reduced. It is, therefore, possible to quickly replace the atmosphere in the storage container body 2 with the N₂ gas without shifting of the positions of the wafers W placed in the storage container body 2. In addition, since the momentum of the N₂ gas can be reduced, the opening/closing lid 12 held by the lid opening/closing mechanism 64 does not shake. This can suppress generation of a particle.

Furthermore, the porous gas injection tube 80 includes the filter function having the filtration property to remove a particle having a diameter of more than a certain value in a range of several nanometers to several hundred nanometers, for example, a diameter of more than 20 nanometers. The nitrogen gas injected from the porous gas injection tube 80 is sucked by the exhaust port 82 and finally exhausted out of the system. Therefore, the nitrogen gas does not leak to a work area where an operator works. High safety against such a leak can be maintained.

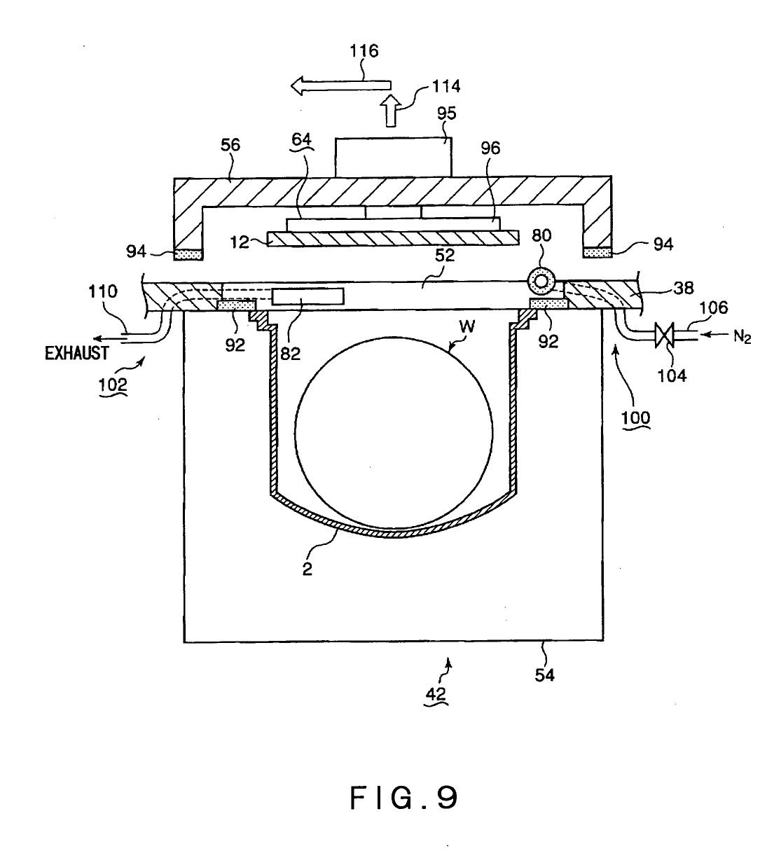

In the abovementioned way, the atmosphere in the storage container body 2 is replaced with the nitrogen gas. The opening/closing door 56 then moves toward a direction indicated by an arrow 114 shown in FIG. 9 and is slightly separated from the opening gate 52. The opening/closing door 56 then slides toward a direction indicated by an arrow 116 and along the guide rails 60 (shown in FIG. 3). These operations cause the storage container body 2 to be open on the side of the wafer transfer area 36 filled with the nitrogen gas atmosphere. The transfer of the wafers W after the storage container body 2 is open is described above.

In the present invention, when the atmosphere in the storage container body 2 is replaced with the nitrogen gas, the inert gas is injected into the storage container body 2 from the gas injection unit 100 having the porous gas injection tube 80. The porous gas injection tube 80 is made of the porous material, has the cylindrical shape, and extends along the inner periphery of the opening gate. In this configuration, since the inert gas is injected from the entire surface of the porous gas injection tube 80, the momentum or the flow rate of the injected inert gas can be sufficiently reduced. Therefore, the replacement of the atmosphere in the storage container body 2 with the inert gas can be quickly, smoothly performed to improve the throughput without shifting of the positions of the wafers W.

### Experimental Example

A comparative experiment was performed using the inlet port mechanism for introducing an object to be treated according to the embodiment of the present invention and a conventional inlet port mechanism for introducing an object to be treated. The evaluation results of the comparative experiment will be described. A storage container body 2 used in the comparative experiment is capable of storing 25 wafers each having a diameter of 300 mm. The flow amount of an N₂ gas was set to be greatest within such an extent that the wafers W did not shake due to the flow rate of the N₂ gas.

In the case where the conventional inlet port mechanism was used, the flow amount of the N₂ gas was approximately 60 L/min. to 90 L/min, and it took 145 seconds to 170 seconds to reduce the concentration of oxygen present in the storage container body 2 to a standard value. In the case where the inlet port mechanism according to the present invention was used, it was possible to feed the N₂ gas with the flow amount of 160 L/min to 200 L/min, and it took 110 seconds to 130 seconds to reduce the concentration of oxygen present in the storage container body 2 to the standard value. It was confirmed that the time it took to replace an atmosphere in the storage container body 2 with the N₂ gas when the inlet port mechanism according to the present invention was used was reduced to three fourth of that when the conventional port mechanism was used.

In the embodiment, the single porous gas injection tube 80 extends along the one side of the quadrangular opening gate 52. The present invention, however, is not limited to this configuration. Two or three porous gas injection tubes 80 may be provided and extend along two or three sides (other than a side of the opening gate 52 along which the exhaust port 82 extends) of the quadrangular opening gate 52.

In the embodiment, the opening/closing door 56 slides in the horizontal direction to open and close the opening gate 52. The present invention, however, is not limited to this configuration. The opening/closing door 56 may move upward and downward with respect to the opening gate 52 to open and close the opening gate 52. In addition, the N₂ gas is used as the inert gas in the embodiment of the present invention. A rare gas such as an Ar gas, a He gas or the like may be used as the inert gas.

In the embodiment, the container transfer area 34 is located at the pre-stage of the wafer transfer area in the treatment system 30. The present invention, however, is not limited to this configuration. The treatment system 30 may be configured to ensure that the container transfer area 34 is replaced with a work area provided in a clean room and an operator directly places the storage container body 2 on the slide base 84 of the stage 54. Furthermore, the semiconductor wafers are used as the objects to be treated. The present invention, however, is not limited to the semiconductor wafers. Glass substrates, LCD substrates, ceramic substrates and the like may be applied to the present invention.

What is claimed is:

1. An inlet port mechanism for introducing an object to be treated, from a storage container body that has an opening/closing lid and is located in a container transfer area into an object transfer area filled with an inert gas atmosphere, comprising:
a partition wall that partitions a space into the container transfer area and the object transfer area and has an opening gate for passing the object to be treated under the condition that the storage container body is in contact with the partition wall;
a stage that is provided at the container transfer area for placing the storage container body thereon;
an opening/closing door mechanism having a opening/closing door that serves to open and close the opening gate on the side of the object transfer area, the opening gate being provided in the partition wall;
a lid opening/closing mechanism that is provided at the opening/closing door and adapted to open and close the opening/closing lid of the storage container body;
gas injection means that extends along an inner periphery of the opening gate to inject an inert gas into the storage container body and has a porous gas injection tube made of a porous material and having a cylindrical shape; and
exhaust means that extends along another inner periphery of the opening gate and has an exhaust port for exhausting an atmosphere that is present in the storage container body and purged by the inert gas injected from the porous gas injection tube.

2. The inlet port mechanism according to claim 1, wherein
the porous gas injection tube includes a filter function having a filtration property to remove a particle having a diameter of more than a certain value in a range of several nanometers to several hundreds nanometers.

3. The inlet port mechanism according to claim 1, wherein
an edge portion of the opening/closing door is bent toward the opening gate, and the opening/closing door has a turned square U-shaped vertical cross section and a turned square U-shaped horizontal cross section.

4. The inlet port mechanism according to claim 1, wherein
the opening gate is formed into a quadrangular shape, and the porous gas injection tube extends along at most three sides of the opening gate.

5. The inlet port mechanism according to claim 1, wherein
the porous gas injection tube is made of one or more selected from the group consisting of a porous metal material, a porous ceramic material and a porous resin material.

6. A treatment system for introducing an object to be treated, from a storage container body that has an opening/closing lid and is located in a container transfer area into an object transfer area filled with an inert gas atmosphere, and subjecting the object to a heat treatment, comprising:
an inlet port mechanism for introducing the object from the container transfer area to the object transfer area;
a treatment chamber that is provided in the object transfer area and in which the object is subjected to the heat treatment;
an object boat that is provided in the object transfer area and capable of mounting a plurality of objects at a plurality of stages;
a port elevating mechanism that is provided in the object transfer area and lifts and lowers the object boat to insert and extract the object boat into and out of the treatment chamber; and
an object transfer mechanism that is provided in the object transfer area and transfers the object between the object boat and the storage container body under the condition that the opening/closing lid of the storage container body is in an open state, wherein
the inlet port mechanism has:
a partition wall that partitions a space into the container transfer area and the object transfer area and has an opening gate for passing the object to be treated under the condition that the storage container body is in contact with the partition wall;
a stage that is provided at the container transfer area for placing the storage container body thereon;
an opening/closing door mechanism having a opening/closing door that serves to open and close the opening gate on the side of the object transfer area, the opening gate being provided in the partition wall;
a lid opening/closing mechanism that is provided at the opening/closing door and adapted to open and close the opening/closing lid of the storage container body;
gas injection means that extends along an inner periphery of the opening gate to inject an inert gas into the storage container body and has a porous gas injection tube made of a porous material and having a cylindrical shape; and
exhaust means that extends along another inner periphery of the opening gate and has an exhaust port for exhausting an atmosphere that is present in the storage container body and purged by the inert gas injected from the porous gas injection tube.
